(19) United States
(12) Patent Application Publication
(10) Pub. No.: US 2025/0015153 A1
(43) Pub. Date: Jan. 9, 2025

(54) CONDUCTIVE CONTACT OF SEMICONDUCTOR DEVICE AND METHOD FOR MANUFACTURING THE SAME

(71) Applicant: TAIWAN SEMICONDUCTOR MANUFACTURING COMPANY, LTD., Hsinchu (TW)

(72) Inventors: Guo-Zhou HUANG, Hsinchu (TW); Huan-Kuan SU, Hsinchu (TW); Wen Han HUNG, Hsinchu (TW); Ling-Sung WANG, Hsinchu (TW)

(73) Assignee: TAIWAN SEMICONDUCTOR MANUFACTURING COMPANY, LTD., Hsinchu (TW)

(21) Appl. No.: 18/346,959

(22) Filed: Jul. 5, 2023

(51) Int. Cl. H01L 29/417; H01L 29/40; H01L 29/423

(52) U.S. Cl. CPC H01L 29/41775; H01L 29/401; H01L 29/4232

(57) ABSTRACT

A method for manufacturing a semiconductor device includes: forming a transistor on a semiconductor substrate, in which the transistor includes a gate structure and a source/drain structure; forming a patterned dielectric layer on the semiconductor substrate, in which the patterned dielectric layer includes an opening extending from a top surface of the patterned dielectric layer to a top surface of the source/drain structure; forming a dielectric contact spacer to cover a sidewall of the opening; and forming a conductive contact in the opening such that the conductive contact is connected to the source/drain structure and is isolated from the gate structure by the dielectric contact spacer and the patterned dielectric layer.

### BACKGROUND

The integration density of various electronic components, such as transistors, diodes, resistors, capacitors, etc., is being continuously improved in integrated circuit industry by continual reduction in minimum feature sizes. As the feature sizes are reduced, a process window for forming conductive contacts to couple the electronic components is reduced, which may cause a bridging problem between the conductive contacts and adjacent conductive features (for example, but not limited to, gate structures) of the electronic components (for example, but not limited to, the transistors).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments, in which conductive contacts are formed.

FIGS. 2 to 10 illustrate schematic views of some intermediate stages of the method depicted in FIG. 1 in accordance with some embodiments.

FIG. 11 illustrate a schematic view of a semiconductor device in which dielectric contact spacers are not formed.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “upwardly,” “upper,” “lower,” “over,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions.

The integration density of various electronic components, such as transistors, diodes, resistors, capacitors, etc., in a semiconductor device is being continuously improved in integrated circuit industry by continual reduction in minimum feature sizes. As the feature sizes in the semiconductor device are continuously reduced, a process window for forming conductive contacts to couple the electronic components is reduced, which may cause a bridging problem between the conductive contacts and adjacent conductive features (for example, but not limited to, gate structures) of the electronic components (for example, but not limited to, the transistors). The bridging problem between the conductive contacts and the adjacent conductive features of the electronic components is a common issue which results in a yield loss, a quality test failure, or the like. The present disclosure is directed to a method for manufacturing a semiconductor device, in which the bridging problem between the conductive contacts and the adjacent conductive features (for example, but not limited to, the gate structures) of the electronic components (for example, but not limited to, the transistors) in the semiconductor device can be alleviated or eliminated by forming dielectric contact spacers between the conductive contacts and the adjacent conductive features (for example, but not limited to, the gate structures) formed in a dielectric layer of the semiconductor device.

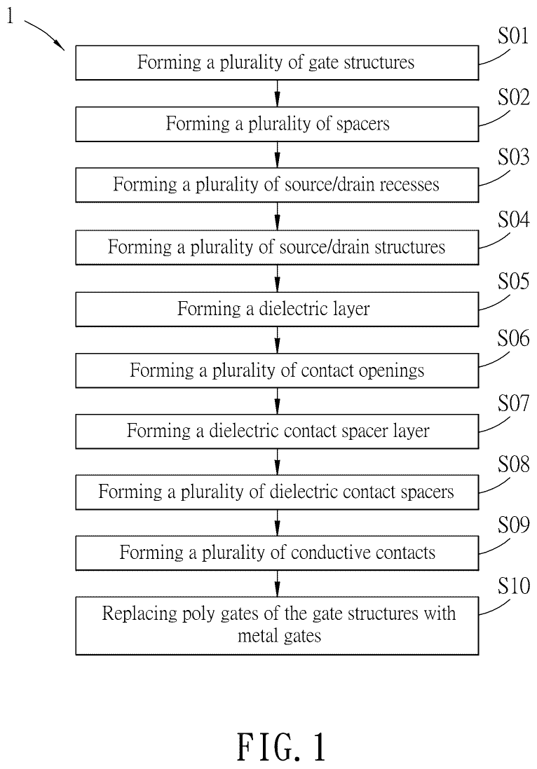

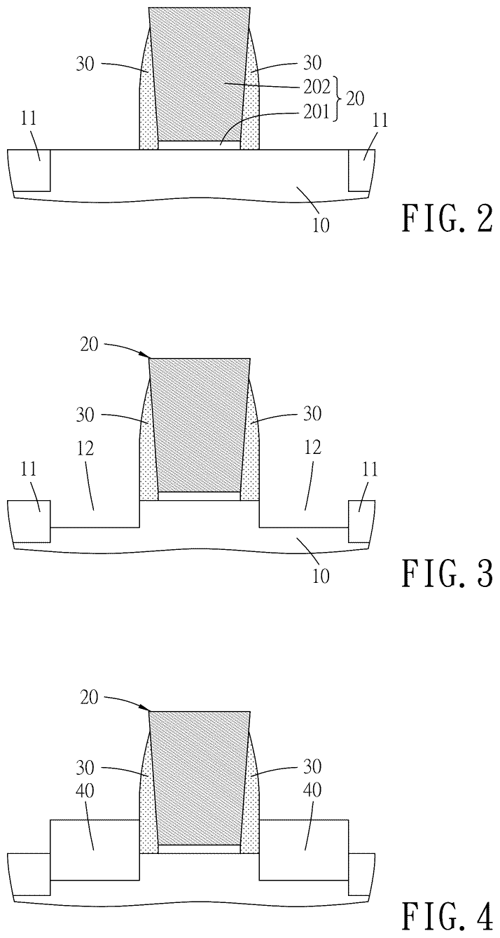

FIG. 1 is a flow diagram illustrating a method 1 for manufacturing a semiconductor device (for example, a semiconductor device 100 shown in FIG. 10) in accordance with some embodiments. FIGS. 2 to 10 illustrate schematic views of some intermediate stages of the method 1 in accordance with some embodiments. Some portions may be omitted in FIGS. 2 to 10 for the sake of brevity. Additional steps can be provided before, after or during the method 1, and some of the steps described herein may be replaced by other steps or be eliminated. Similarly, further additional features may be present in the semiconductor device 100, and/or features present may be replaced or eliminated in additional embodiments.

Referring to FIG. 1 and the example illustrated in FIG. 2, the method 1 begins at step S01, where a plurality of gate structures 20 are formed on a semiconductor substrate 10. One of the gate structures 20 is shown in FIG. 2 for the purpose of simplicity.

In some embodiments, the semiconductor substrate 10 may include, for example, but not limited to, an elemental semiconductor or a compound semiconductor. In some embodiments, the elemental semiconductor includes a single species of atoms, such as silicon (Si) or germanium (Ge) in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, but not limited to, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 10 may include a multilayer compound semiconductor structure. In some embodiments, the semiconductor substrate 10 may be a semiconductor on insulator (SOI) (e.g., silicon germanium on insulator (SGOI)). Generally, an SOI substrate includes a layer of a semiconductor material such as epitaxial silicon, germanium, silicon germanium, or combinations thereof. Other suitable semiconductor materials are within the contemplated scope of the present disclosure. The SOI substrate may be doped with a P-type dopant, for example, but not limited to, boron (Br), aluminum (Al), or gallium (Ga). Other suitable dopant materials are within the contemplated scope of the present disclosure. Alternatively, the SOI substrate may be doped with an N-type dopant, for example, but not limited to, nitrogen (N), phosphorous (P), or arsenic (As). Other suitable dopant materials are within the contemplated scope of the present disclosure.

A plurality of isolation structures 11 are formed in the semiconductor substrate 10 to define a plurality of portions of the semiconductor substrate 10 as a plurality of active regions (also referred to as oxide definition (OD) regions), in which active devices (for example, but not limited to, transistors) may be formed. Two of the isolation structures 11 are shown in FIG. 2 for the purpose of simplicity. In some embodiments, the isolation structures 11 are, for example, but not limited to, shallow trench isolation (STI) structures. In some alternative embodiments, the isolation structures 11 may be, for example, but not limited to, deep trench isolation (DTI) structures. In some embodiments in which the isolation structures 11 are the STI structures, the isolation structures 11 may be formed by etching a plurality of shallow trenches (not shown) in the semiconductor substrate 10, and filling the shallow trenches with a dielectric material. In some embodiments, the dielectric material for forming the isolation structures 11 may include a low dielectric constant (low-k) dielectric material. In some embodiments, examples of the low-k dielectric material may include, for example, but not limited to, silicon oxide (SiOx), silicon nitride (SiNx), silicon oxynitride (SiON), silicon carbonitride (SiCN), silicon oxycarbide (SiOC), silicon oxycarbonitride (SiOCN), silicon carbide (SiC), and combinations thereof. Other suitable low-k dielectric materials are within the contemplated scope of the present disclosure. In some embodiments, the dielectric material for forming the isolation structures 11 includes silicon oxide (SiOx).

In some embodiments, each of the gate structures 20 may include a gate dielectric 201 disposed on the semiconductor substrate 10 and a ploy gate 202 disposed on the gate dielectric 201. In some embodiments, each of the gate structures 20 may further include a hard mask portion (not shown) disposed on the poly gate 202 opposite to the gate dielectric 201. In some embodiments, the gate structures 20 may be formed by the following processes.

A gate dielectric material layer, a polysilicon material layer, and a hard mask material layer are formed sequentially on the semiconductor substrate 10. In some embodiments, the gate dielectric material layer may be formed on the semiconductor substrate 10 by a suitable process as known to those skilled in the art of semiconductor fabrication, for example, but not limited to, chemical vapor deposition (CVD), atomic layer deposition (ALD), high density plasma CVD (HDPCVD), remote plasma CVD (RPCVD), plasma enhanced CVD (PECVD), or plasma enhanced ALD (PEALD). Other suitable processes are within the contemplated scope of the present disclosure. In some embodiments, the gate dielectric material layer may include a high-k dielectric material, for example, but not limited to, hafnium oxide, silicon nitride, silicon oxynitride, titanium oxide, hafnium zirconium oxide, tantalum oxide, hafnium silicon oxide, zirconium oxide, zirconium silicon oxide, lanthanum oxide, aluminum oxide, yttrium oxide, strontium titanate, barium titanate, barium zirconate, lanthanum silicon oxide, aluminum silicon oxide, hafnium lanthanum oxide, hafnium silicon oxide, aluminum silicon oxide, hafnium tantalum oxide, hafnium titanium oxide, other suitable high-k materials, or combinations thereof. Other suitable dielectric materials are within the contemplated scope of the present disclosure. In some embodiments, the polysilicon material layer may be formed on the gate dielectric material layer by a suitable process as known to those skilled in the art of semiconductor fabrication, for example, but not limited to, CVD, ALD, HDPCVD, RPCVD, PECVD, or PEALD. Other suitable processes are within the contemplated scope of the present disclosure. In some embodiments, the hard mask material layer may be formed on the polysilicon material layer by a suitable process as known to those skilled in the art of semiconductor fabrication, for example, but not limited to, physical vapor deposition (PVD), CVD, ALD, PEALD, thermal ALD, PECVD, spin-on coating, or other suitable processes. In some embodiments, the hard mask material layer may include, for example, but not limited to, silicon oxide, silicon nitride, silicon carbide, silicon oxycarbide, silicon oxynitride, silicon carbonitride, silicon oxycarbonitride, cobalt, ruthenium, tungsten, tungsten nitride, tungsten carbide, titanium nitride, zirconium oxide, aluminum oxide, yttrium oxide, aluminum oxynitride, hafnium oxide, hafnium zirconium oxide, hafnium silicon oxide, hafnium silicon oxynitride, zirconium silicon oxide, hafnium zirconium silicon oxide, hafnium aluminum oxide, hafnium aluminum nitride, zirconium aluminum oxide, ytterbium oxide, or combinations thereof. Other suitable materials are within the contemplated scope of the present disclosure. The hard mask material layer is then patterned using photolithography and photoresist developing technology as known to those skilled in the art of semiconductor fabrication. An opening pattern formed in the hard mask material layer is then transferred to the polysilicon material layer and the gate dielectric material layer by one or more etching processes (for example but not limited to, a wet etching process, a dry etching process, or a combination thereof) to form the gate structures 20 on the semiconductor substrate 10.

Referring to FIG. 1 and the example illustrated in FIG. 2, the method 1 proceeds to step S02, where a plurality of spacers 30 are formed to laterally cover the gate structures 20. Each pair of the spacers 30 laterally cover a corresponding one of the gate structures 20. In some embodiments, the spacers 30 may be formed by the following processes.

A spacer material layer (not shown) is conformally deposited to cover the gate structures 20, the semiconductor substrate 10, and the isolation structures 11. The conformal deposition may be performed by a suitable deposition process as known to those skilled in the art of semiconductor fabrication, for example but not limited to, CVD, PECVD, ALD, or PEALD. Other suitable processes are within the contemplated scope of the present disclosure. In some embodiments, the spacer material layer may include, for example, but not limited to, a low-k dielectric material. In some embodiments, examples of the low-k dielectric material may include, for example, but not limited to, silicon oxide, silicon nitride, silicon carbide, silicon oxycarbide, silicon oxynitride, silicon carbonitride, silicon oxycarbonitride, and combinations thereof. Other suitable low-k dielectric materials are within the contemplated scope of the present disclosure. Thereafter, the spacer material layer is anisotropically etched by, for example, but not limited to, an anisotropic dry etching process, to etch away horizontal portions of the spacer material layer to form a plurality of the spacers 30 extending upwardly from the semiconductor substrate 10, such that each pair of the spacers 30 laterally cover a corresponding one of the gate structures 20. However, as shown in FIG. 2, the spacer material layer may be over-etched by the anisotropic dry etching process, such that lateral surfaces of the gate structures 20 are only partially covered by the spacers 30 and upper portions of the gate structures 20 are exposed from the spacers 30.

Referring to FIG. 1 and the example illustrated in FIG. 3, the method 1 proceeds to step S03, where a plurality of source/drain recesses 12 are formed. In some embodiments, the source/drain recesses 12 may be formed by recessing the semiconductor substrate 10 using an anisotropic etching process. Each of the gate structures 20 laterally covered by the spacers 30 is disposed between two corresponding ones of the source/drain recesses 12, and each of the source/drain recesses 12 is disposed between a corresponding one of the isolation structures 11 and a corresponding one of the gate structures 20 laterally covered by the spacers 30. In some embodiments, the anisotropic etching process may be an anisotropic dry etching process. Other suitable anisotropic etching processes as known to those skilled in the art of semiconductor fabrication are within the contemplated scope of the present disclosure.

Referring to FIG. 1 and the example illustrated in FIG. 4, the method 1 proceeds to step S04, where a plurality of source/drain structures 40 are formed. Two of the source/drain structures 40 are separated from each other by a corresponding one of the gate structures 20 laterally covered by the spacers 30. The source/drain structures 40 are respectively formed in the source/drain recesses 12 of the structure shown in FIG. 3. In some embodiments, the source/drain structures 40 may be formed by epitaxially growing a semiconductor material in the source/drain recesses 12 of the structure shown in FIG. 3 through a selective epitaxial growth (SEG) process. In some embodiments, the source/drain structures 40 may be, for example, but not limited to, crystalline silicon (or other suitable semiconductor materials) in-situ doped with a P-type dopant during the SEG process, so as to form PMOS transistors. The P-type dopant may be, for example, but not limited to, boron, aluminum, gallium, indium, BF₂, or combinations thereof. Other suitable materials are within the contemplated scope of the present disclosure. In some embodiments, the source/drain structures 40 may include one or multiple layers of the semiconductor material. In some embodiments, the source/drain structures 40 may be fabricated by forming a SiGe alloy layer in the recesses 12 of the structure shown in FIG. 3 through the SEG process and forming a Si cap layer on top of the SiGe alloy layer, followed by implanting a P-type light doping grain (for example but not limited to, boron, aluminum, gallium, indium, BF₂, other suitable materials, or combinations thereof). In some embodiments, the source/drain structures 40 may be, for example, but not limited to, crystalline silicon (or other suitable semiconductor materials) in-situ doped with an N-type dopant during the SEG process, so as to form NMOS transistors. The N-type dopant may be, for example, but not limited to, phosphorous, nitrogen, arsenic, antimony, or combinations thereof. Other suitable materials are within the contemplated scope of the present disclosure. In some embodiments, the source/drain structures 40 may be fabricated by forming a SiGe alloy layer in the recesses 12 of the structure shown in FIG. 3 through the SEG process and forming a Si cap layer on top of the SiGe alloy layer, followed by implanting an N-type light doping drain (for example but not limited to, phosphorous, nitrogen, arsenic, antimony, other suitable materials, or combinations thereof).

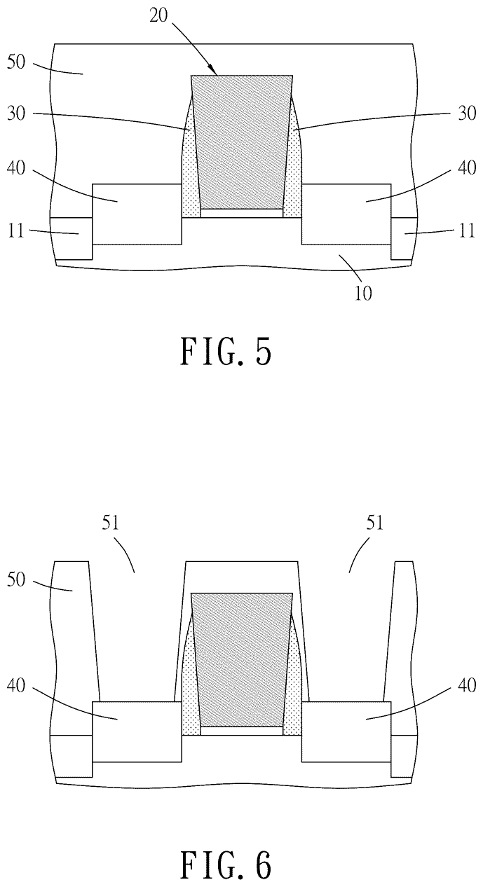

Referring to FIG. 1 and the example illustrated in FIG. 5, the method 1 proceeds to step S05, where a dielectric layer 50 is formed on the structure shown in FIG. 4. The dielectric layer 50 is formed on the semiconductor substrate 10 to cover the isolation structures 11, the source/drain structures 40, the gate structures 20, and the spacers 30. The dielectric layer 50 is made of a dielectric material. In some embodiments, examples of the dielectric material may include, for example, but not limited to, silicon oxide (SiOx), silicon nitride (SiNx), silicon oxynitride (SiON), silicon carbonitride (SiCN), silicon oxycarbide (SiOC), silicon oxycarbonitride (SiOCN), silicon carbide (SIC), phosphosilicate glass (PSG), borophosphosilicate glass (BPSG), spin-on glass (SOG), fluorinated silica glass (FSG), carbon doped silicon oxide (e.g., SiCOH), BLACK DIAMOND® (Applied Materials of Santa Clara, Calif.), Xerogel, Acrogel, amorphous fluorinated carbon, Parylene, BCB (bis-benzocyclobutenes), Flare, SILK® (Dow Chemical, Midland, Mich.), polyimide, and combinations thereof. Other suitable dielectric materials are within the contemplated scope of the present disclosure. In some embodiments, the dielectric layer 50 is made of a low-k dielectric material. In some embodiments, examples of the low-k dielectric material may include, for example, but not limited to, silicon oxide (SiOx), silicon nitride (SiNx), silicon oxynitride (SiON), silicon carbonitride (SiCN), silicon oxycarbide (SiOC), silicon oxycarbonitride (SiOCN), silicon carbide (SiC), an extreme low-k (ELK) dielectric material, and combinations thereof. Other suitable low-k dielectric materials are within the contemplated scope of the present disclosure. In some embodiments, the dielectric layer 50 may be deposited on the semiconductor substrate 10 to have a suitable thickness by, for example, but not limited to, CVD, PECVD, ALD, PEALD, spin-on, sputtering, or other suitable processes.

Referring to FIG. 1 and the example illustrated in FIG. 6, the method 1 proceeds to step S06, where a plurality of contact openings 51 are formed. The contact openings 51 are formed through the dielectric layer 50 to expose the source/drain structures 40 from the contact openings 51, respectively. That is, the contact openings 51 extend from a top surface of the dielectric layer 50 to top surfaces of the source/drain structures 40. In some embodiments, the contact openings 51 may be formed by the following processes.

A mask layer (for example, but not limited to, a hard mask layer) is deposited on the dielectric layer 50 of the structure shown in FIG. 5. Examples of a material suitable for forming the mask layer include, for example, but not limited to, silicon oxide, silicon nitride, silicon carbide, silicon oxycarbide, silicon oxynitride, silicon carbonitride, silicon oxycarbonitride, tungsten nitride, tungsten carbide, titanium nitride, zirconium oxide, aluminum oxide, yttrium oxide, aluminum oxynitride, hafnium oxide, hafnium zirconium oxide, hafnium silicon oxide, hafnium silicon oxynitride, zirconium silicon oxide, hafnium zirconium silicon oxide, hafnium aluminum oxide, hafnium aluminum nitride, zirconium aluminum oxide, ytterbium oxide, and combinations thereof. Other suitable materials are within the contemplated scope of the present disclosure. The mask layer may be formed on the dielectric layer 50 by a suitable deposition process as is known in the art of semiconductor fabrication, such as PVD, CVD, ALD, PEALD, thermal ALD, PECVD, or spin-on coating. Other suitable techniques are within the contemplated scope of the present disclosure. A photoresist layer (not shown) is then formed on the mask layer by a suitable fabrication technique known to those skilled in the art of semiconductor fabrication, for example, but not limited to, a spin-on technique. Other suitable techniques are within the contemplated scope of the present disclosure. The photoresist layer is then patterned using a suitable photolithography technique to form a pattern of recesses. For example, the photoresist layer is exposed to light for patterning, followed by developing to form the pattern of the recesses. The pattern of the recesses formed in the photoresist layer is transferred to the mask layer using one or more etching processes, for example, but not limited to, a wet etching process, a dry etching process, a reactive ion etching process, a neutral beam etching process, or the like. After the pattern of the recesses is transferred to the mask layer, the photoresist layer may be removed by, for example, but not limited to, an ashing process, such that a patterned mask layer (not shown) is formed on the dielectric layer 50. One or more of the patterned mask layers may be used for patterning the dielectric layer 50. Thereafter, the dielectric layer 50 of the structure shown in FIG. 5 is patterned by one or more etching processes (for example, but not limited to, a dry etching process, a wet etching process, or a combination thereof) through a pattern of openings formed in the patterned mask layer to form the contact openings 51.

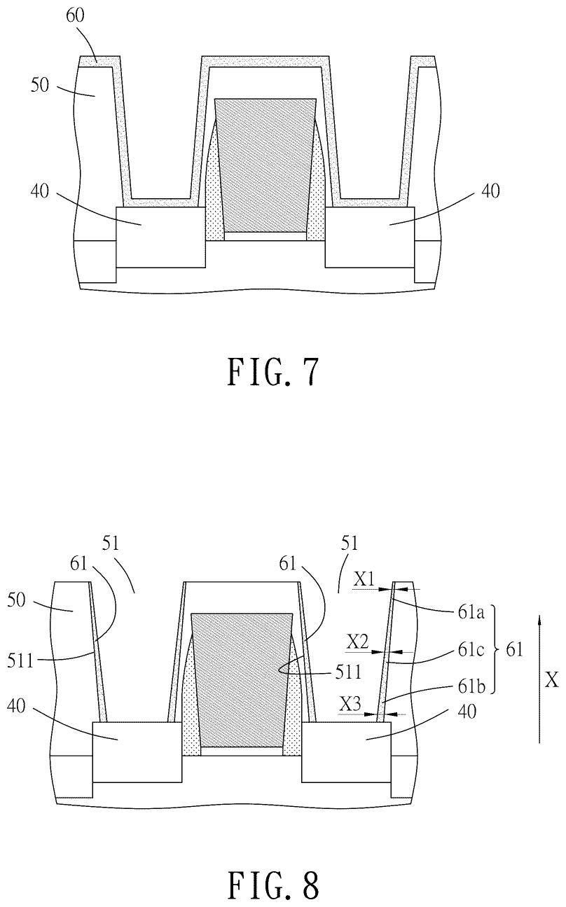

Referring to FIG. 1 and the example illustrated in FIG. 7, the method 1 proceeds to step S07, where a dielectric contact spacer layer 60 is formed. The dielectric contact spacer layer 60 is conformally formed on the structure shown in FIG. 6 to cover the dielectric layer 50 and the source/drain structures 40. In some embodiments, The conformal deposition may be performed by a suitable deposition process as known to those skilled in the art of semiconductor fabrication, for example but not limited to, CVD, PECVD, ALD, or PEALD. Other suitable processes are within the contemplated scope of the present disclosure. In some embodiments, the dielectric contact spacer layer 60 is made of a low-k dielectric material. In some embodiments, examples of the low-k dielectric material may include, for example, but not limited to, silicon oxide (SiOx), silicon nitride (SiNx, for example, but not limited to, nitrogen-rich silicon nitride), silicon oxynitride (SiON), silicon carbonitride (SiCN), silicon oxycarbide (SiOC), silicon oxycarbonitride (SiOCN), silicon carbide (SiC), an ELK dielectric material, and combinations thereof. Other suitable low-k dielectric materials are within the contemplated scope of the present disclosure. In some embodiments, the low-k dielectric material for forming the dielectric contact spacer layer 60 may be the same as the low-k dielectric material for forming the dielectric layer 50. In some alternative embodiments, the low-k dielectric material for forming the dielectric contact spacer layer 60 may be different from the low-k dielectric material for forming the dielectric layer 50. In some embodiments, the dielectric contact spacer layer 60 has a thickness ranging from about 2 nanometers (nm) to about 300 nm.

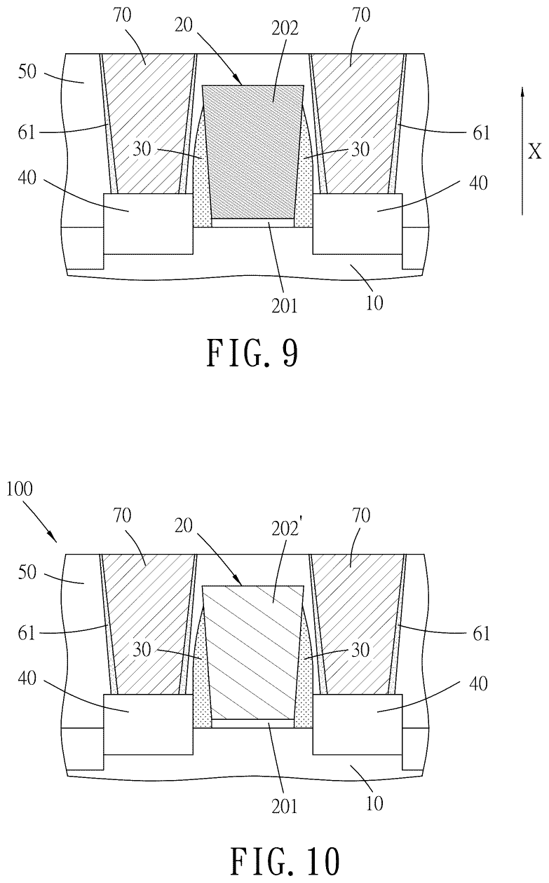

Referring to FIG. 1 and the example illustrated in FIG. 8, the method 1 proceeds to step S08, where a plurality of dielectric contact spacers 61 are formed. In some embodiments, the dielectric contact spacers 61 may be formed by etching away horizontal portions of the dielectric contact spacer layer 60 disposed on the top surface of the dielectric layer 50 and the top surfaces of the source/drain structures 40 (see FIG. 7) using an anisotropic etching process (for example, but not limited to, an anisotropic dry etching process), such that each of the dielectric contact spacers 61 fully covers a sidewall 511 of a corresponding one of the contact openings 51 formed in the dielectric layer 50. As described above, the thickness of the dielectric contact spacer layer 60 ranges from about 2 nm to about 300 nm. If the thickness of the dielectric contact spacer layer 60 is less than 2 nm, each of the dielectric contact spacers 61 thus formed may not fully cover the sidewall 511 of the corresponding one of the contact openings 51. If the thickness of the dielectric contact spacer layer 60 is greater than 300 nm, the remaining volumes of the contact openings 51, after formation of the dielectric contact spacers 61, may not be sufficient for forming conductive contacts 70 shown in FIG. 9 (which will be described hereinafter).

Each of the dielectric contact spacers 61 has a thickness which decreases gradually along a direction (X) from the top surfaces of the source/drain structures 40 to the top surface of the dielectric layer 50, so as to reduce contact resistance produced by the dielectric contact spacers 61. Each of the dielectric contact spacers 61 includes an upper portion 61a proximate to the top surface of the dielectric layer 50, a lower portion 61b proximate to the top surface of a corresponding one of the source/drain structures 40, and an intermediate portion 61c disposed between the upper portion 61a and the lower portion 61b such that the upper portion 61a and the lower portion 61b are interconnected to each other through the intermediate portion 61c. The upper portion 61a of each of the dielectric contact spacers 61 has a thickness (X1), the intermediate portion 61c of each of the dielectric contact spacers 61 has a thickness (X2), and the lower portion 61b of each of the dielectric contact spacers 61 has a thickness (X3). The thickness (X1) is less than the thickness (X2), and the thickness (X2) is less than the thickness (X3). In some embodiments, a difference between the thickness (X2) and the thickness (X1) ranges from about 0.1 nm to about 10 nm. In some embodiments, a difference between the thickness (X3) and the thickness (X2) ranges from about 0.1 nm to about 10 nm.

Referring to FIG. 1 and the example illustrated in FIG. 9, the method 1 proceeds to step S09, where a plurality of conductive contacts 70 are formed. The conductive contacts 70 are formed in the dielectric layer 50. Lateral surfaces of the conductive contacts 70 are fully covered by the dielectric contact spacers 61, such that the gate structures 20, which are only partially covered by and exposed from the spacers 30, can be isolated from the conductive contacts 70 by the dielectric contact spacers 61 and the dielectric layer 50. Specifically, an upper portion of each of the gate structures 20, which is not covered by and is exposed from a corresponding one of the spacers 30, can be isolated from a corresponding one of the conductive contacts 70 by a corresponding one of the dielectric contact spacers 61 and a corresponding one portion of the dielectric layer 50. The conductive contacts 70 are connected to the source/drain structures 40, respectively. In some embodiments, the conductive contacts 70 are formed by conformally depositing a glue material layer (not shown) on the structure shown in FIG. 8, and then depositing a conductive material to fill the contact openings 51 of the structure shown in FIG. 8, followed by removing excess of the glue material layer and the conductive material formed on the dielectric layer 50 by a planarization technique, such as chemical mechanical planarization (CMP). In some embodiments, the glue material layer may include, for example, but not limited to, tantalum (Ta), tantalum nitride (TaN), titanium (Ti), titanium nitride (TiN), cobalt (Co), or combinations thereof. Other suitable glue materials are within the contemplated scope of the present disclosure. In some embodiments, the conductive material may include, for example, but not limited to, a metal or metal-containing material such as copper (Cu), tungsten (W), cobalt (Co), ruthenium (Ru), titanium (Ti), titanium nitride (TiN), tantalum (Ta), tantalum nitride (TaN), molybdenum (Mo), nickel (Ni), platinum (Pt), a low resistivity metal constituent, other suitable materials, alloys thereof, or combinations thereof. Other suitable conductive materials are within the contemplated scope of the present disclosure. In some embodiments, deposition of the glue material layer and the conductive material may be performed by a suitable technique, such as CVD, ALD, plating, or other suitable deposition techniques.

Referring to FIG. 1 and the example illustrated in FIGS. 9 and 10, the method 1 proceeds to step S10, where the poly gates 202 of the gate structures 20 are replaced with metal gates 202′ so as to form a plurality of transistors on the semiconductor substrate 10. Each of the transistors includes a corresponding one of the gate structures 20 and a corresponding one pair of the source/drain structures 40 separated from each other by the corresponding one of the gate structures 20. The poly gates 202 of the gate structures 20 of the structure shown in FIG. 9 are removed by one or more etching processes (for example, but not limited to, a wet etching process, a dry etching process, or a combination thereof) to form voids (not shown) defined by the dielectric layer 50, the spacers 30, and the gate dielectrics 201. A metal filling layer is then formed in the voids by one or more deposition processes, for example, but not limited to, CVD, ALD, HDPCVD, sub-atmospheric CVD (SACVD), molecular layer deposition (MLD), PVD, or sputtering, to form the metal gates 202′. Other suitable processes are within the contemplated scope of the present disclosure. In some embodiments, the metal filling layer may include a barrier sub-layer, a work function sub-layer, and a filling material sub-layer. The barrier sub-layer may prevent diffusion of metal into the gate dielectrics 201. Examples of a material suitable for the work function sub-layer may include, for example, but not limited to, titanium, aluminum, tantalum carbide, tantalum carbide nitride, tantalum silicon nitride, and combinations thereof. Examples of a material suitable for the filling material sub-layer may include, for example, but not limited to, aluminum, tungsten, copper, and other conductive metals, and combinations thereof.

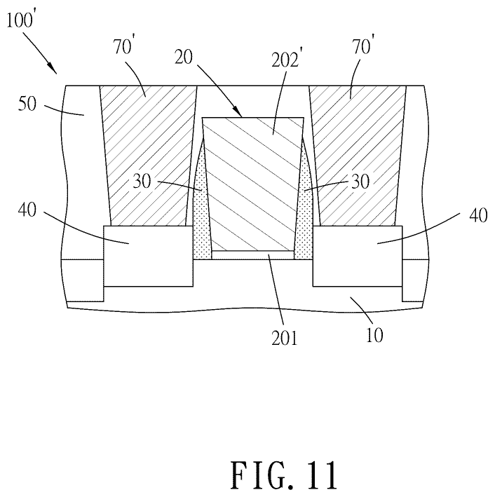

Referring to the example illustrated in FIG. 11, a semiconductor device 100′ is manufactured by directly forming conductive contacts 70′ in the contact openings 51 of the structure shown in FIG. 6 (i.e. step S07 and S08 for formation of the dielectric contact spacers 61 are not performed).

As described above, as shown in FIG. 2, when the spacers 30 are formed by etching away the horizontal portions of the spacer layer using the anisotropic etching process (for example, but not limited to, the anisotropic dry etching process), the spacer layer may be over-etched by the anisotropic dry etching process, such that lateral surfaces of the gate structures 20 may only be partially covered by the spacers 30. In the present disclosure, as shown in FIGS. 8 to 10, the dielectric contact spacers 61 are formed to fully cover the sidewalls 511 of the contact openings 51 formed in the dielectric layer 50 before the conductive contacts 70 are formed. Compared to spacing distances between the gate structures 20 and the conductive contacts 70′ in the semiconductor device 100′ shown in FIG. 11, spacing distances between the gate structures 20 and the conductive contacts 70 of the semiconductor device 100 shown in FIG. 10 are increased. Therefore, the bridging problem between the conductive contacts 70 and the gate structures 20 due to exposure of the upper portions of the gate structures 20 from the spacers 30 can be alleviated or eliminated by forming the dielectric contact spacers 61 between the conductive contacts 70 and the dielectric layer 50.

In a method for manufacturing a semiconductor device of the present disclosure, dielectric contact spacers made of a low-k dielectric material are formed to fully cover sidewalls of contact openings formed in a dielectric layer before conductive contacts are formed to be connected to source/drain structures. Therefore, a bridging problem between the conductive contacts and gate structures due to over-etching of a dielectric spacer layer for forming spacers which causes upper portions of the gate structures to be exposed from the spacers, can be alleviated or eliminated by forming the dielectric contact spacers between the conductive contacts and the dielectric layer, thereby increasing spacing distances between the gate structures and the conductive contacts.

In accordance with some embodiments of the present disclosure, a method for manufacturing a semiconductor device includes: forming a transistor on a semiconductor substrate, the transistor including a gate structure and a source/drain structure; forming a patterned dielectric layer on the semiconductor substrate, the patterned dielectric layer including an opening extending from a top surface of the patterned dielectric layer to a top surface of the source/drain structure; forming a dielectric contact spacer to cover a sidewall of the opening; and forming a conductive contact in the opening such that the conductive contact is connected to the source/drain structure and is isolated from the gate structure by the dielectric contact spacer and the patterned dielectric layer.

In accordance with some embodiments of the present disclosure, the method for manufacturing a semiconductor device further includes, prior to formation of the patterned dielectric layer, forming a spacer partially covering a lateral surface of the gate structure to expose an upper portion of the gate structure from the spacer.

In accordance with some embodiments of the present disclosure, the upper portion of the gate structure is isolated from the conductive contact by the dielectric contact spacer and a portion of the patterned dielectric layer.

In accordance with some embodiments of the present disclosure, the dielectric contact spacer has a thickness which decreases gradually along a direction from the top surface of the source/drain structure to the top surface of the patterned dielectric layer.

In accordance with some embodiments of the present disclosure, the dielectric contact spacer includes an upper portion proximate to the top surface of the patterned dielectric layer, a lower portion proximate to the top surface of the source/drain structure, and an intermediate portion disposed between the upper portion and the lower portion. The lower portion has a thickness. The intermediate portion has a thickness less than the thickness of the lower portion. The upper portion has a thickness less than the thickness of the intermediate portion.

In accordance with some embodiments of the present disclosure, a difference between the thickness of the lower portion and the thickness of the intermediate portion ranges from about 0.1 nm to about 10 nm.

In accordance with some embodiments of the present disclosure, a difference between the thickness of the intermediate portion and the thickness of the upper portion ranges from about 0.1 nm to about 10 nm.

In accordance with some embodiments of the present disclosure, the dielectric contact spacer is formed from a dielectric contact spacer layer which is made of a low-k dielectric material selected from silicon oxide, silicon nitride, silicon oxynitride, silicon carbonitride, silicon oxycarbide, silicon oxycarbonitride, silicon carbide, an extreme low-k dielectric material, or combinations thereof.

In accordance with some embodiments of the present disclosure, a method for manufacturing a semiconductor device includes: forming a transistor on a semiconductor substrate, the transistor including a gate structure and a source/drain structure; forming a patterned dielectric layer on the semiconductor substrate, the patterned dielectric layer including an opening extending from a top surface of the patterned dielectric layer to a top surface of the source/drain structure; conformally depositing a dielectric contact spacer layer on the patterned dielectric layer and the source/drain structure; anisotropically etching the dielectric contact spacer layer to form a dielectric contact spacer covering a sidewall of the opening; and forming a conductive contact in the opening such that the conductive contact is connected to the source/drain structure and is isolated from the gate structure by the dielectric contact spacer and the patterned dielectric layer.

In accordance with some embodiments of the present disclosure, the method for manufacturing a semiconductor device further includes, prior to formation of the patterned dielectric layer, forming a spacer partially covering a lateral surface of the gate structure to expose an upper portion of the gate structure from the spacer.

In accordance with some embodiments of the present disclosure, the upper portion of the gate structure is isolated from the conductive contact by the dielectric contact spacer and a portion of the patterned dielectric layer.

In accordance with some embodiments of the present disclosure, the dielectric contact spacer layer is made of a low-k dielectric material selected from silicon oxide, silicon nitride, silicon oxynitride, silicon carbonitride, silicon oxycarbide, silicon oxycarbonitride, silicon carbide, an extreme low-k dielectric material, or combinations thereof.

In accordance with some embodiments of the present disclosure, the dielectric contact spacer layer has a thickness ranging from 2 nm to 300 nm.

In accordance with some embodiments of the present disclosure, the dielectric contact spacer has a thickness which decreases gradually along a direction from the top surface of the source/drain structure to the top surface of the patterned dielectric layer.

In accordance with some embodiments of the present disclosure, a semiconductor device includes a semiconductor substrate; a transistor disposed on the semiconductor substrate and including a gate structure and a source/drain structure; a dielectric layer disposed on the semiconductor substrate to cover the gate structure; a conductive contact disposed in the dielectric layer and connected to the source/drain structure; and a dielectric contact spacer covering a lateral surface of the conductive contact such that the conductive contact is isolated from the gate structure by the dielectric contact spacer and the dielectric layer.

In accordance with some embodiments of the present disclosure, the semiconductor further includes a spacer partially covering a lateral surface of the gate structure to expose an upper portion of the gate structure from the spacer.

In accordance with some embodiments of the present disclosure, the upper portion of the gate structure is isolated from the conductive contact by the dielectric contact spacer and a portion of the dielectric layer.

In accordance with some embodiments of the present disclosure, the dielectric contact spacer has a thickness which decreases gradually along a direction from a top surface of the source/drain structure to a top surface of the dielectric layer.

In accordance with some embodiments of the present disclosure, the dielectric contact spacer includes an upper portion proximate to the top surface of the dielectric layer, a lower portion proximate to the top surface of the source/drain structure, and an intermediate portion disposed between the upper portion and the lower portion. The lower portion has a thickness. The intermediate portion has a thickness less than the thickness of the lower portion. The upper portion has a thickness less than the thickness of the intermediate portion.

In accordance with some embodiments of the present disclosure, a difference between the thickness of the lower portion and the thickness of the intermediate portion ranges from 0.1 nm to 10 nm, and a difference between the thickness of the intermediate portion and the thickness of the upper portion ranges from 0.1 nm to 10 nm.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a transistor on a semiconductor substrate, the transistor including a gate structure and a source/drain structure;
forming a patterned dielectric layer on the semiconductor substrate, the patterned dielectric layer including an opening extending from a top surface of the patterned dielectric layer to a top surface of the source/drain structure;
forming a dielectric contact spacer to cover a sidewall of the opening; and
forming a conductive contact in the opening such that the conductive contact is connected to the source/drain structure and is isolated from the gate structure by the dielectric contact spacer and the patterned dielectric layer.

2. The method as claimed in claim 1, further comprising, prior to formation of the patterned dielectric layer, forming a spacer partially covering a lateral surface of the gate structure to expose an upper portion of the gate structure from the spacer.

3. The method as claimed in claim 2, wherein the upper portion of the gate structure is isolated from the conductive contact by the dielectric contact spacer and a portion of the patterned dielectric layer.

4. The method as claimed in claim 1, wherein the dielectric contact spacer has a thickness which decreases gradually along a direction from the top surface of the source/drain structure to the top surface of the patterned dielectric layer.

5. The method as claimed in claim 4, wherein the dielectric contact spacer includes an upper portion proximate to the top surface of the patterned dielectric layer, a lower portion proximate to the top surface of the source/drain structure, and an intermediate portion disposed between the upper portion and the lower portion, the lower portion having a thickness, the intermediate portion having a thickness less than the thickness of the lower portion, the upper portion having a thickness less than the thickness of the intermediate portion.

6. The method as claimed in claim 5, wherein a difference between the thickness of the lower portion and the thickness of the intermediate portion ranges from 0.1 nm to 10 nm.

7. The method as claimed in claim 5, wherein a difference between the thickness of the intermediate portion and the thickness of the upper portion ranges from 0.1 nm to 10 nm.

8. The method as claimed in claim 1, wherein the dielectric contact spacer is formed from a dielectric contact spacer layer which is made of a low-k dielectric material selected from silicon oxide, silicon nitride, silicon oxynitride, silicon carbonitride, silicon oxycarbide, silicon oxycarbonitride, silicon carbide, an extreme low-k dielectric material, or combinations thereof.

9. A method for manufacturing a semiconductor device, comprising:
forming a transistor on a semiconductor substrate, the transistor including a gate structure and a source/drain structure;
forming a patterned dielectric layer on the semiconductor substrate, the patterned dielectric layer including an opening extending from a top surface of the patterned dielectric layer to a top surface of the source/drain structure;
conformally depositing a dielectric contact spacer layer on the patterned dielectric layer and the source/drain structure;
anisotropically etching the dielectric contact spacer layer to form a dielectric contact spacer covering a sidewall of the opening; and
forming a conductive contact in the opening such that the conductive contact is connected to the source/drain structure and is isolated from the gate structure by the dielectric contact spacer and the patterned dielectric layer.

10. The method as claimed in claim 9, further comprising, prior to formation of the patterned dielectric layer, forming a spacer partially covering a lateral surface of the gate structure to expose an upper portion of the gate structure from the spacer.

11. The method as claimed in claim 10, wherein the upper portion of the gate structure is isolated from the conductive contact by the dielectric contact spacer and a portion of the patterned dielectric layer.

12. The method as claimed in claim 9, wherein the dielectric contact spacer layer is made of a low-k dielectric material selected from silicon oxide, silicon nitride, silicon oxynitride, silicon carbonitride, silicon oxycarbide, silicon oxycarbonitride, silicon carbide, an extreme low-k dielectric material, or combinations thereof.

13. The method as claimed in claim 9, wherein the dielectric contact spacer layer has a thickness ranging from 2 nm to 300 nm.

14. The method as claimed in claim 9, wherein the dielectric contact spacer has a thickness which decreases gradually along a direction from the top surface of the source/drain structure to the top surface of the patterned dielectric layer.

15. A semiconductor device, comprising:
a semiconductor substrate;
a transistor disposed on the semiconductor substrate and including a gate structure and a source/drain structure;
a dielectric layer disposed on the semiconductor substrate to cover the gate structure;
a conductive contact disposed in the dielectric layer and connected to the source/drain structure; and
a dielectric contact spacer covering a lateral surface of the conductive contact such that the conductive contact is isolated from the gate structure by the dielectric contact spacer and the dielectric layer.

16. The semiconductor device as claimed in claim 15, further comprising a spacer partially covering a lateral surface of the gate structure to expose an upper portion of the gate structure from the spacer.

17. The semiconductor device as claimed in claim 16, wherein the upper portion of the gate structure is isolated from the conductive contact by the dielectric contact spacer and a portion of the dielectric layer.

18. The semiconductor device as claimed in claim 15, wherein the dielectric contact spacer has a thickness which decreases gradually along a direction from a top surface of the source/drain structure to a top surface of the dielectric layer.

19. The semiconductor device as claimed in claim 18, wherein the dielectric contact spacer includes an upper portion proximate to the top surface of the dielectric layer, a lower portion proximate to the top surface of the source/drain structure, and an intermediate portion disposed between the upper portion and the lower portion, the lower portion having a thickness, the intermediate portion having a thickness less than the thickness of the lower portion, the upper portion having a thickness less than the thickness of the intermediate portion.

20. The semiconductor device as claimed in claim 19, wherein a difference between the thickness of the lower portion and the thickness of the intermediate portion ranges from 0.1 nm to 10 nm, and a difference between the thickness of the intermediate portion and the thickness of the upper portion ranges from 0.1 nm to 10 nm.
